(19) United States
(12) Patent Application Publication
(10) Pub. No.: US 2012/0227904 A1
(43) Pub. Date: Sep. 13, 2012

(54) CYLINDER CABINET AND SEMICONDUCTOR MANUFACTURING SYSTEM

(75) Inventor: Shinji AKIYOSHI, Mie (JP)

(73) Assignee: Kabushiki Kaisha Toshiba, Tokyo (JP)

(21) Appl. No.: 13/238,324

(22) Filed: Sep. 21, 2011

(30) Foreign Application Priority Data
Mar. 11, 2011 (JP) 2011-054571

(51) Int. Cl. C23C 16/455; H01L 21/306; F16K 51/00

(52) U.S. Cl. 156/345.26; 137/455; 118/715

(57) ABSTRACT

According to one embodiment, a cylinder cabinet includes a controller performing control in such a way that when the amount of a residual gas in a first gas container becomes a predetermined amount or smaller, a gas supply pipe that supplies gas is switched from a first gas supply pipe to a second gas supply pipe. Moreover, the controller performs control in such a way that the residual gas in the first gas container is recovered into the recovery container during a period in which the gas is supplied from a second gas container. Furthermore, the controller performs control in such a way that when the first gas container is replaced with a new gas container, the inside of the first gas supply pipe is purged with the residual gas stored in the recovery container.

### CROSS-REFERENCE TO RELATED APPLICATIONS

This application is based upon and claims the benefit of priority from Japanese Patent Application No. 2011-054571, filed on Mar. 11, 2011; the entire contents of which are incorporated herein by reference.

### FIELD

Embodiments described herein relate generally to a cylinder cabinet and a semiconductor manufacturing system.

### BACKGROUND

In semiconductor manufacturing apparatuses, various material gases and the like are used depending on the steps of semiconductor manufacturing processes. Such a material gas is supplied from a cylinder cabinet disposed adjacent to a semiconductor production plant to a semiconductor manufacturing apparatus through gas pipes installed within the semiconductor production plant.

In a cylinder cabinet of the related art, for example, two gas containers are prepared, and gas is supplied to a semiconductor manufacturing apparatus using any one of the two gas containers. Moreover, a residual gas weight and a primary pressure are measured while the gas is being supplied to the semiconductor manufacturing apparatus. Moreover, when the residual gas weight within the first gas container reaches a lower-limit residual gas weight or primary pressure at which stable supply of gas is ensured, a gas supply source is changed from the first gas container to the second gas container to continue supplying the gas.

Thus, a predetermined amount of gas still remains in the first gas container. Since the first gas container is removed in such a state and then a new gas container is attached, the residual gas is returned to a gas maker with the residual gas therein and is then disposed of. Due to such wasteful disposal of gas, there is a problem in that it increases the cost of usage of gas. Thus, it is desirable to reduce wasteful discarding of gas.

### BRIEF DESCRIPTION OF THE DRAWINGS

FIG. 1 is a diagram illustrating a configuration of a cylinder cabinet according to a first embodiment;

FIG. 2 is a diagram illustrating an internal state of the cylinder cabinet according to the first embodiment when a residual gas is recovered;

FIG. 3 is a diagram illustrating an internal state of the cylinder cabinet according to the first embodiment when a process gas is purged using a recovery gas in a gas recovery container;

FIG. 4 is a diagram illustrating the flow of a process of supplying a process gas to a semiconductor manufacturing apparatus;

FIG. 5 is a diagram illustrating a configuration of a cylinder cabinet according to a second embodiment;

FIG. 6 is a diagram illustrating an internal state of the cylinder cabinet according to the second embodiment when a residual gas is recovered;

FIG. 7 is a diagram illustrating an internal state of the cylinder cabinet according to the second embodiment when a process gas is purged using a recovery gas in a gas recovery container; and

FIG. 8 is a diagram illustrating another configuration example of a gas recovery mechanism.

### DETAILED DESCRIPTION

In general, according to one embodiment, a cylinder cabinet is provided. The cylinder cabinet includes a first gas supply pipe that is connected to a first gas container for gas to be supplied to an external apparatus so as to supply the gas in the first gas container toward the external apparatus; and a second gas supply pipe that is connected to a second gas container for gas to be supplied to the external apparatus so as to supply the gas in the second gas container toward the external apparatus. The cylinder cabinet further includes a gas recovery pipe that is connected to a recovery container for recovering and storing the residual gases in the first and second gas containers so as to supply the residual gas in the gas container toward the recovery container; and a vacuum pipe that is connected to the recovery container so as to vacuum the inside of the recovery container before the residual gas is stored in the recovery container. The cylinder cabinet further includes automatic valves that are provided on the first and second gas supply pipes, the gas recovery pipe, and the vacuum pipe, respectively so as to block or open the flow of the gas; and a controller that controls the automatic valves to thereby control the flow of the gas and the residual gas so that the gas is supplied to the external apparatus through any one of the first and second gas supply pipes. The controller performs control in such a way that when the amount of the residual gas in the first gas container becomes a predetermined amount or smaller, a gas supply pipe that supplies the gas is switched from the first gas supply pipe to the second gas supply pipe. The controller performs control in such a way that the residual gas in the first gas container is recovered into the recovery container during a period in which the gas is supplied from the second gas container. The controller performs control in such a way that when the first gas container is replaced with a new gas container, the inside of the first gas supply pipe is purged with the residual gas stored in the recovery container.

Exemplary embodiments of a cylinder cabinet and a semiconductor manufacturing system will be explained below in detail with reference to the accompanying drawings. The present invention is not limited to the following embodiments.

### First Embodiment

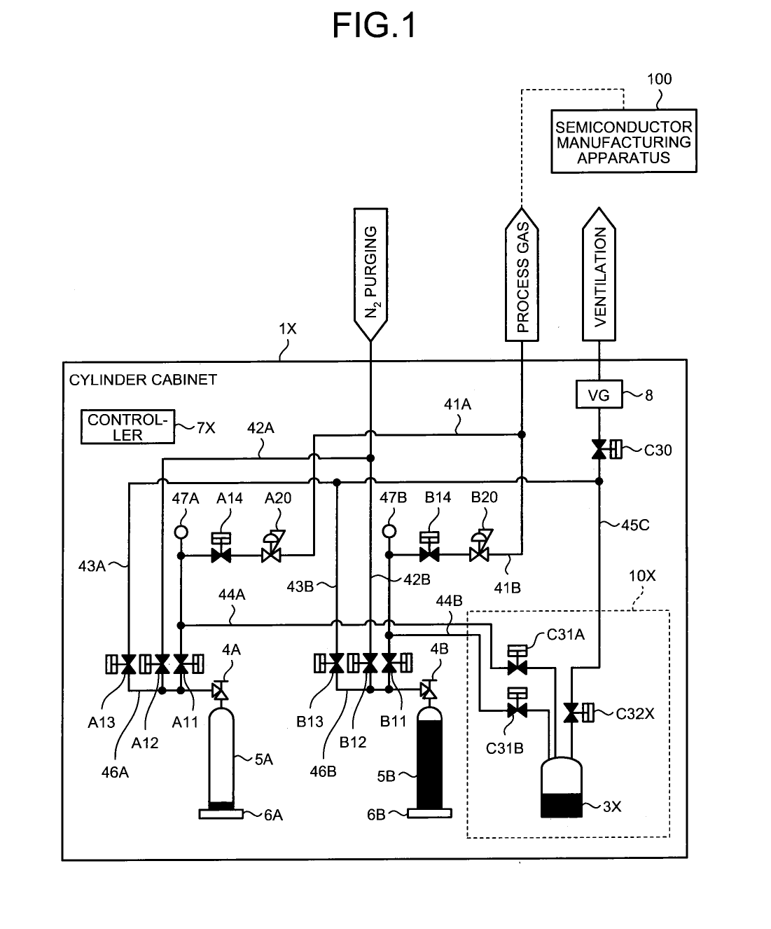

FIG. 1 is a diagram illustrating a configuration of a cylinder cabinet according to the first embodiment. A semiconductor manufacturing system includes a cylinder cabinet 1X and a semiconductor manufacturing apparatus 100. The cylinder cabinet 1X is an apparatus that supplies a process gas to the semiconductor manufacturing apparatus 100 or the like using two gas containers (gas bombes). The cylinder cabinet 1X of the present embodiment includes a gas recovery mechanism 10X that recovers gas remaining in a gas container. Moreover, the cylinder cabinet 1X includes a controller 7X.

The cylinder cabinet 1X includes a gas container 5A, a gas container 5B, and a gas recovery container 3X. The cylinder cabinet 1X includes a process gas supply pipe 41A that delivers the process gas from the gas container 5A toward the semiconductor manufacturing apparatus, an N₂ gas supply pipe 42A that supplies an N₂ gas to a pipe connected to the gas container 5A, and a ventilation pipe 43A that ventilates the process gas or N₂ gas remaining in the pipe to the outside (ventilation through a vent).

Similarly, the cylinder cabinet 1X includes a process gas supply pipe 41B that delivers the process gas from the gas container 5B toward the semiconductor manufacturing apparatus, an N₂ gas supply pipe 42B that supplies an N₂ gas to a pipe connected to the gas container 5B, and a ventilation pipe 43B that ventilates the process gas or N₂ gas remaining in the pipe to the outside.

Moreover, the cylinder cabinet 1X also includes a gas recovery pipe 44A that sends gas remaining in the gas container 5A into the gas recovery container 3X, a gas recovery pipe 44B that sends gas remaining in the gas container 5B into the gas recovery container 3X, and a vacuum pipe 45C for vacuuming the inside of the gas recovery container 3X.

The N₂ gas supply pipe 42A on the side of the gas container 5A is a pipe for purging (N₂ purging) the process gas in the pipe with an N₂ gas, and sends an N₂ gas into a pipe (a container proximity pipe 46A described later), to which the gas container 5A is connected, when replacing the used-up gas container 5A with a new gas container 5A. Similarly, the N₂ gas supply pipe 42B on the side of the gas container 5B is a pipe for purging (N₂ purging) the process gas in the pipe with an N₂ gas, and sends an N₂ gas into a pipe (a container proximity pipe 46B described later), to which the gas container 5B is connected, when replacing the used-up gas container 5B with a new gas container 5B.

The process gas supply pipe 41A on the side of the gas container 5A includes an automatic valve A14, a pressure adjustment valve A20, and a pressure meter 47A. Moreover, the N₂ gas supply pipe 42A on the side of the gas container 5A includes an automatic valve A12, and the ventilation pipe 43A on the side of the gas container 5A includes an automatic valve A13.

Similarly, the process gas supply pipe 41B on the side of the gas container 5B includes an automatic valve B14, a pressure adjustment valve B20, and a pressure meter 47B. Moreover, the N₂ gas supply pipe 42B on the side of the gas container 5B includes an automatic valve B12, and the ventilation pipe 43B on the side of the gas container 5B includes an automatic valve B13.

The gas recovery pipe 44A is a pipe that is connected to the process gas supply pipe 41A on a side closer to the upstream side (the gas container 5A side) more than the automatic valve A14 and is connected to the gas recovery container 3X, and an automatic valve C31A is provided on this pipe.

Similarly, the gas recovery pipe 44B is a pipe that is connected to the process gas supply pipe 41B on a side closer to the upstream side (the gas container 5B side) more than the automatic valve B14 and is connected to the gas recovery container 3X, and an automatic valve C31B is provided on this pipe. Moreover, the vacuum pipe 45C includes an automatic valve C32X.

The process gas supply pipes 41A and 41B are connected to each other on the side of a delivery port from which a process gas is delivered to the semiconductor manufacturing apparatus, and a process gas delivered from the process gas supply pipe 41A or 41B is fed into the semiconductor manufacturing apparatus.

Moreover, the N₂ gas supply pipes 42A and 42B are connected to each other on the side of a feeding port to which an N₂ gas is fed. Moreover, the ventilation pipes 43A and 43B, and the vacuum pipe 45C are connected to each other on the side of a ventilation port. In addition, an automatic valve C30 and a vacuum pressure adjustment valve (Vacuum Generator: VG) 8 are provided on a pipe extending from the connection portion to the ventilation port.

Moreover, the pipe that connects the ventilation pipes 43A and 43B and the vacuum pipe 45C is connected to a vacuum ventilation device at the outside of the cylinder cabinet 1X. Moreover, the pipe that connects the N₂ gas supply pipes 42A and 42B is connected to a supply source (an N₂ gas container) of the N₂ gas at the outside of the cylinder cabinet 1X.

Moreover, the process gas supply pipe 41A and the gas recovery pipe 44A are connected to each other on the side of the gas container 5A, and an automatic valve 11A is provided on a pipe that extends from this connection portion to the gas container 5A.

Similarly, the process gas supply pipe 41B and the gas recovery pipe 44B are connected to each other on the side of the gas container 5B, and an automatic valve 11B is provided on a pipe that extends from this connection portion to the gas container 5B.

The automatic valves A11 to A13 are disposed in the proximity of the gas container 5A. Moreover, a predetermined pipe (a container proximity pipe 46A) is connected between the automatic valves A11 to A13 and the gas container 5A.

Similarly, the automatic valves B11 to B13 are disposed in the proximity of the gas container 5B. Moreover, a predetermined pipe (a container proximity pipe 46B) is connected between the automatic valves B11 to B13 and the gas container 5B.

The gas recovery mechanism 10X is configured to include a part of the vacuum pipe 45C, a part of the gas recovery pipe 44A, a part of the gas recovery pipe 44B, and the automatic valves C31A, C31B, and C32X. The gas recovery mechanism 10X includes the gas recovery container 3X, whereby a residual gas in the gas container 5A and a residual gas in the gas container 5B are recovered into the gas recovery container 3X.

Moreover, a weight scale 6A is provided at a location where the gas container 5A is provided, and a weight scale 6B is provided at a location where the gas container 5B is provided. The weight scales 6A and 6B each are devices that measure the weight of the residual gas in the gas containers 5A and 5B. The gas containers 5A and 5B include container valves 4A and 4B, respectively, and the container valves 4A and 4B open when gas is delivered.

The controller 7X controls the supply of the process gas, the recovery of the residual gas, the N₂ purging, the ventilation of the N₂ gas, the process gas purging, and the like by controlling the automatic valves A11 to A14, B11 to B14, C30, C31A, C31B, and C32X, the pressure adjustment valves A20 and B20, the VG 8, and the like. The automatic valves A11 to A14, B11 to B14, C30, C31A, C31B, and C32X are valves that close or open the flow of gas, and the flow of gas is switched by controlling the respective automatic valves.

For example, the valves (the automatic valve B14 and the like) on the side of the gas container 5B are closed when the process gas is supplied to the semiconductor manufacturing apparatus using the gas container 5A. Moreover, the automatic valves A12, A13, and C31A are closed, and the automatic valves A11 and A14 and the container valve 4A are opened. In this way, the process gas is supplied to the semiconductor manufacturing apparatus through the container proximity pipe 46A and the process gas supply pipe 41A.

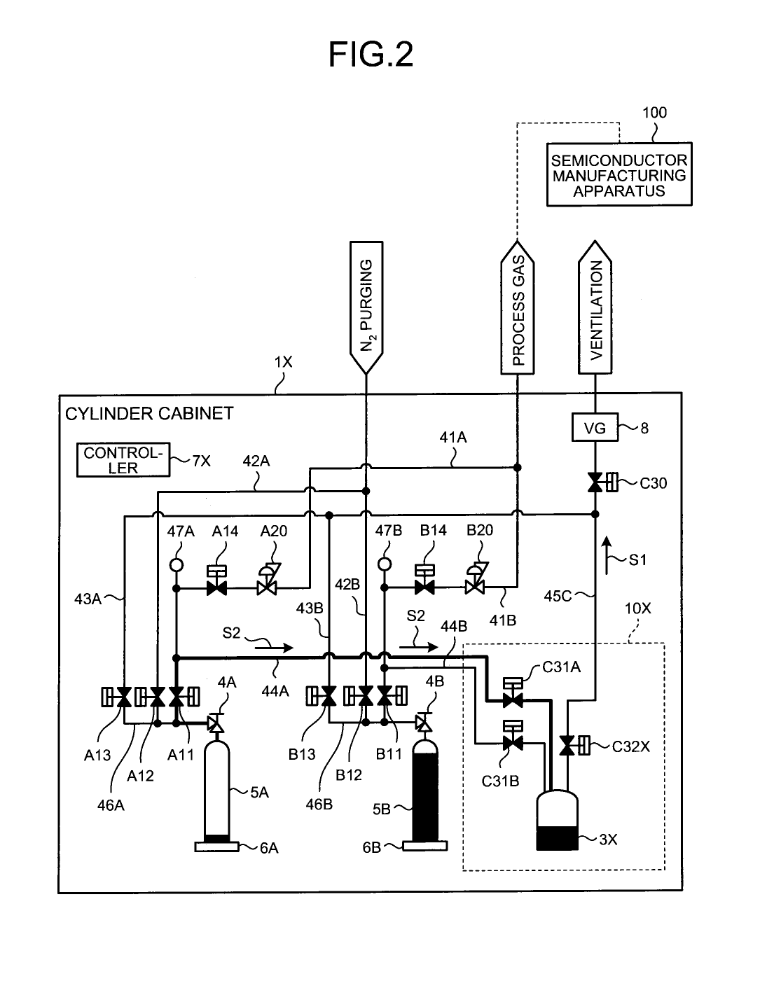

Here, a residual gas recovery process according to the first embodiment will be explained. FIG. 2 is a diagram illustrating the internal state of the cylinder cabinet according to the first embodiment when recovering the residual gas. When the residual gas in the gas container 5A is recovered into the gas recovery container 3X, the automatic valves C31A and C31B are closed, and the automatic valves C30 and C32X are opened. In this way, the inside of the gas recovery container 3X is vacuumed (S1) through the vacuum pipe 45C.

Moreover, after the inside of the gas recovery container 3X is vacuumed, the automatic valve C32X is closed. Moreover, the automatic valves A12 to A14 are closed, and the automatic valves A11 and C31A and the container valve 4A are opened. In this way, the residual gas is recovered (S2) into the gas recovery container 3X. In other words, the residual gas in the gas container 5A is pulled into the gas recovery container 3X through the container proximity pipe 46A and the gas recovery pipe 44A. After that, when the recovery of the residual gas is completed, the automatic valves A11 and C31A and the container valve 4A are closed.

Moreover, after the recovery of the residual gas in the gas container 5A is finished, when the N₂ purging is performed on the container proximity pipe 46A with an N₂ gas, the automatic valves A11 and A13 and the container valve 4A are closed, and the automatic valve A12 is opened. In this way, the N₂ gas in the container proximity pipe 46A is fed, whereby the concentration of the process gas decreases.

Moreover, when the N₂ gas in the container proximity pipe 46A is ventilated, the automatic valves A11 and A12 and the container valve 4A are closed, and the automatic valves A13 and C30 are opened. In this way, the process gas is ventilated from the container proximity pipe 46A together with the N₂ gas.

The N₂ purging of the container proximity pipe 46A with an N₂ gas (including feeding of the N₂ gas and ventilation (degassing) of the N₂ gas) is performed a plurality of times, for example. In this way, the concentration of the process gas in the container proximity pipe 46A decreases to be lower than a predetermined value.

After the process gas disappears from the container proximity pipe 46A, the gas container 5A is removed from the cylinder cabinet 1X in a state where the automatic valves A11 to A13 are closed. Moreover, a new gas container 5A is attached to the cylinder cabinet 1X.

When a process gas is supplied from the new gas container 5A to the semiconductor manufacturing apparatus, it is necessary to fill (purge) the gas recovery pipe 44A, the container proximity pipe 46A, and a part (the upstream side) of the process gas supply pipe 41A in advance with a process gas. In the present embodiment, the pipes are purged with a process gas using the recovery gas in the gas recovery container 3X. In the following description, the pipes which are purged with the process gas will be referred to as process gas purging target pipes.

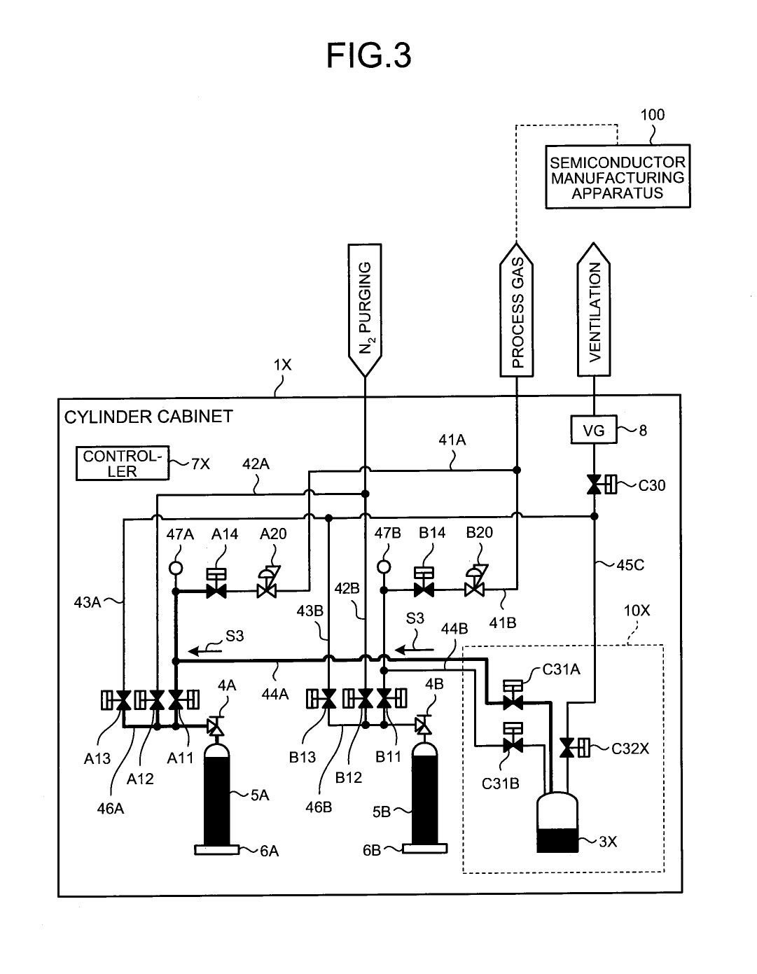

FIG. 3 is a diagram illustrating the internal state of the cylinder cabinet according to the first embodiment when the process gas purging is performed using the recovery gas in the gas recovery container. When the process gas purging is performed using the recovery gas in the gas recovery container 3X (the residual gas in the gas container 5A recovered from the gas container 5A before replacement), the automatic valves C32X, C31B, and A12 to A14 are closed, and the automatic valves A11 and C31A are opened. In this way, the process gas is fed into the process gas purging target pipes, whereby the concentration of the process gas increases.

Moreover, when ventilating the process gas in the container proximity pipe 46A, the automatic valve C31A is closed, and the automatic valves A11, A13, and C30 are opened. In this way, gases other than the process gas are ventilated from the process gas purging target pipes together with the process gas.

The process gas purging of the process gas purging target pipes (including feeding of the process gas and ventilation (degassing) of the process gas) is performed a plurality of times, for example. In this way, the concentration of the process gas in the process gas purging target pipes increases to be higher than a predetermined value. As above, the process gas is purged using the residual gas (S3) from the gas recovery container 3X, and the process gas purging target pipes are filled with the process gas. Specifically, a pipe between the automatic valve A11 and the automatic valve A14 within the process gas supply pipe 41A, the gas recovery pipe 44A, and the container proximity pipe 46A are filled with the process gas from the gas recovery container 3X.

The supply of the process gas using the gas container 5B, the recovery of the residual gas from the gas container 5B, the N₂ purging, the ventilation of the N₂ gas, the process gas purging, and the like are the same as the processes for the gas container 5A, and description thereof will not be provided.

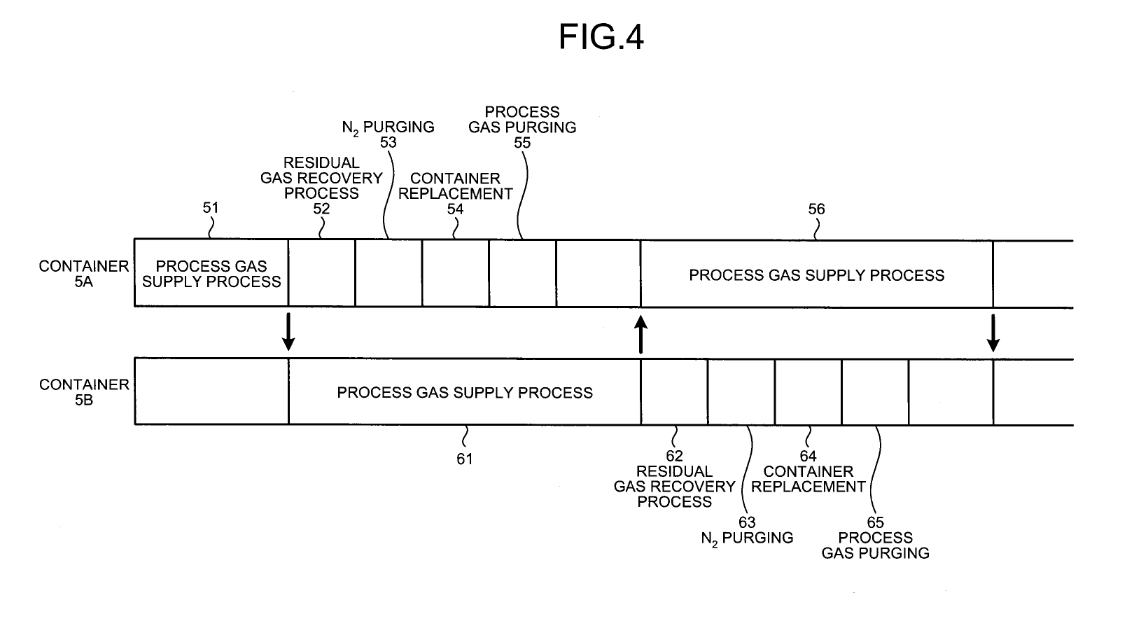

Next, the flow of the process of supplying the process gas to the semiconductor manufacturing apparatus will be described. FIG. 4 is a diagram illustrating the flow of the process of supplying the process gas to the semiconductor manufacturing apparatus. In the cylinder cabinet 1X, the process gas in the gas container 5A and the process gas in the gas container 5B are alternately supplied to the semiconductor manufacturing apparatus. In this case, the process gas in the gas container 5A is used until the remaining amount thereof reaches a predetermined amount (a predetermined remaining weight or a predetermined primary pressure). After that, the gas supply source is changed from the gas container 5A to the gas container 5B to continue supplying the process gas. Moreover, the process gas in the gas container 5B is used until the remaining amount thereof reaches a predetermined remaining weight or a predetermined primary pressure. In this way, the switching from the gas container 5A to the gas container 5B and the switching from the gas container 5B to the gas container 5A are sequentially performed.

(Process Gas Supply Process 51)

For example, a process gas supply process 51 of supplying the process gas from the gas container 5A to the semiconductor manufacturing apparatus is performed. In this case, the weight scale 6A measures the weight of the gas container 5A, and the pressure meter 47A measures the pressure (primary pressure) of the pipe between the automatic valve A14 and the automatic valve A11. When the weight measured by the weight scale 6A is smaller than a predetermined value, or the pressure measured by the pressure meter 47A is smaller than a predetermined value, the process gas supply process of supplying the process gas from the gas container 5A stops, and a process gas supply process 61 of supplying the process gas from the gas container 5B starts.

(Residual Gas Recovery Process 52)

After the process gas supply process 51 of supplying the process gas from the gas container 5A stops, a residual gas recovery process 52 starts on the side of the gas container 5A. When the residual gas in the gas container 5A is recovered into the gas recovery container 3X, the automatic valves C31A and C31B are closed, and the automatic valves C30 and C32X are opened. In this way, the inside of the gas recovery container 3X is vacuumed through the vacuum pipe 45C.

After the inside of the gas recovery container 3X is vacuumed, the automatic valve C32X is closed. Moreover, the automatic valves A12 to A14 are closed, and the automatic valves A11 and C31A and the container valve 4A are opened. In this way, the residual gas in the gas container 5A is pulled into the gas recovery container 3X through the gas recovery pipe 44A. After that, when the residual gas recovery process 52 is completed, the automatic valves A11 and C31A and the container valve 4A are closed.

(N₂ Purging 53)

After the residual gas recovery process 52 of recovering the residual gas in the gas container 5A is finished, an N₂ purging 53 of the container proximity pipe 46A is performed. In this case, the automatic valves A11 and A13 and the container valve 4A are closed, and the automatic valve A12 is opened. In this way, the N₂ gas is fed into the container proximity pipe 46A, whereby the concentration of the process gas decreases.

Moreover, when the N₂ gas in the container proximity pipe 46A is ventilated, the automatic valves A11 and A12 and the container valve 4A are closed, and the automatic valves A13 and C30 are opened. In this way, the process gas is ventilated from the container proximity pipe 46A together with the N₂ gas. The N₂ purging of the container proximity pipe 46A using the N₂ gas is performed a plurality of times, for example.

(Container Replacement 54)

After the process gas disappears from the container proximity pipe 46A, the gas container 5A is removed from the cylinder cabinet 1X in a state where the automatic valves A11 to A13 and the container valve 4A are closed. Moreover, a new gas container 5A is attached to the cylinder cabinet 1X.

(Process Gas Purging 55)

Moreover, a process gas purging 55 is performed on the process gas purging target pipes on the side of the gas container 5A using the recovery gas in the gas recovery container 3X. In this way, preparations for supplying the process gas from the gas container 5A are completed, and the process gas is brought into a state of being supplied from the gas container 5A.

For example, the residual gas recovery process 52, the N₂ purging 53, the container replacement 54, the process gas purging 55 on the side of the gas container 5A are performed during the process gas supply process 61 of supplying the process gas from the gas container 5B to the semiconductor manufacturing apparatus.

(Process Gas Supply Process 61)

After the process gas supply process 51, when the process gas supply process 61 of supplying the process gas from the gas container 5B to the semiconductor manufacturing apparatus is performed, the automatic valves B12 and B13 and the automatic valve C31B are closed, and the automatic valves B11 and B14 and the container valve 4B are opened.

In this case, the weight scale 6B measures the weight of the gas container 5B, and the pressure meter 47B measures the pressure (primary pressure) of the pipe between the automatic valve B14 and the automatic valve B11. When the weight measured by the weight scale 6B is smaller than a predetermined value, or the pressure measured by the pressure meter 47B is smaller than a predetermined value, the process gas supply process of supplying the process gas from the gas container 5B stops, and a process gas supply process 56 of supplying the process gas from the gas container 5A starts. Specifically, the automatic valve B14 on the side of the gas container 5B is closed, and the automatic valves A13 and A14 and the container valve 4A on the side of the gas container 5A are opened.

(Residual Gas Recovery Process 62)

After the process gas supply process 61 of supplying the process gas from the gas container 5B stops, a residual gas recovery process 62 starts on the side of the gas container 5B. When the residual gas in the gas container 5B is recovered into the gas recovery container 3X, the automatic valves C31A and C31B are closed, and the automatic valves C30 and C32X are opened. In this way, the inside of the gas recovery container 3X is vacuumed through the vacuum pipe 45C.

After the inside of the gas recovery container 3X is vacuumed, the automatic valve C32X is closed. Moreover, the automatic valves B12 to B14 are closed, and the automatic valves B11 and C31B and the container valve 4B are opened. In this way, the residual gas in the gas container 5B is pulled into the gas recovery container 3X through the gas recovery pipe 44B. After that, when the residual gas recovery process 62 is completed, the automatic valves B11 and C31B and the container valve 4B are closed.

(N₂ Purging 63)

After the residual gas recovery process 62 of recovering the residual gas in the gas container 5B is finished, an N₂ purging 63 of the container proximity pipe 46B is performed. In this case, the automatic valves B11 and B13 and the container valve 4B are closed, and the automatic valve B12 is opened. In this way, the N₂ gas is fed into the container proximity pipe 46B, whereby the concentration of the process gas decreases.

Moreover, when the N₂ gas in the container proximity pipe 46B is ventilated, the automatic valves B11 and B12 and the container valve 4B are closed, and the automatic valves B13 and C30 are opened. In this way, the process gas is ventilated from the container proximity pipe 46B together with the N₂ gas. The N₂ purging of the container proximity pipe 46B using the N₂ gas is performed a plurality of times, for example.

(Container Replacement 64)

After the process gas disappears from the container proximity pipe 46B, the gas container 5B is removed from the cylinder cabinet 1X in a state where the automatic valves B11 to B13 and the container valve 4B are closed. Moreover, a new gas container 5B is attached to the cylinder cabinet 1X.

(Process Gas Purging 65)

Moreover, a process gas purging 65 is performed on the process gas purging target pipes on the side of the gas container 5B using the recovery gas in the gas recovery container 3X. In this way, preparations for supplying the process gas from the gas container 5B are completed, and the process gas is brought into a state of being supplied from the gas container 5B.

(Process Gas Supply Process 56)

After the process gas supply process 61, a process gas supply process 56 of supplying the process gas from the gas container 5A to the semiconductor manufacturing apparatus is performed. The process gas supply process 56 using the gas container 5A is the same as the process gas supply process 51.

As above, during the period when the process gas supply process is performed on one container, the residual gas recovery process, the N₂ purging, the container replacement, and the process gas purging are performed on the other container. Moreover, when the amount of the residual gas on one container reaches a predetermined amount or smaller, the process gas supply process is performed on the other container. Moreover, during the period when the process gas supply process is performed on the other container, the residual gas recovery process, the N₂ purging, the container replacement, and the process gas purging are performed on one container. As above, in the cylinder cabinet 1X, the gas containers 5A and 5B alternately perform the process gas supply process.

In the semiconductor manufacturing apparatus, semiconductor devices are manufactured using the process gas from the cylinder cabinet 1X. In addition, the cylinder cabinet 1X may supply the process gas to apparatuses other than the semiconductor manufacturing apparatus.

The semiconductor manufacturing apparatus is a deposition apparatus, an etching apparatus, and the like, for example. When semiconductor devices (semiconductor integrated circuits) are manufactured, a mask such as a photomask is manufactured, and exposure is performed on a wafer on which a resist is applied using the mask, and then, the wafer is developed and whereby a resist pattern is formed on the wafer. Moreover, the lower side of the wafer is etched using the resist pattern as a mask. In this way, an actual pattern corresponding to the resist pattern is formed on the wafer. When semiconductor devices are manufactured, a deposition process, an exposure process, a developing process, an etching process, and the like are repeated for each layer.

In the present embodiment, although a case in which the N₂ gas supply pipes 42A and 42B and the vacuum pipe 45C are connected to perform vacuuming using the same vacuuming device has been described, a plurality of vacuuming devices may be prepared. In this case, at least one of the N₂ gas supply pipes 42A and 42B and the vacuum pipe 45C is connected to the respective vacuuming device.

In addition, three or more gas containers may be provided in the cylinder cabinet 1X. In this case, the process gas supply pipe, the N₂ gas supply pipe, the ventilation pipe, the gas recovery pipe, and the like are provided to each gas container. Moreover, gas other than the N₂ gas may be used for purging. A gas which does not cause a problem even when it is discharged into a clean room when replacing the gas container may be appropriately selected and used.

As above, according to the first embodiment, the residual gas in the gas container 5A or 5B is recovered by the gas recovery container 3X, and the recovered residual gas is used for purging the process gas, it is possible to reduce wasteful discarding of gas.

### Second Embodiment

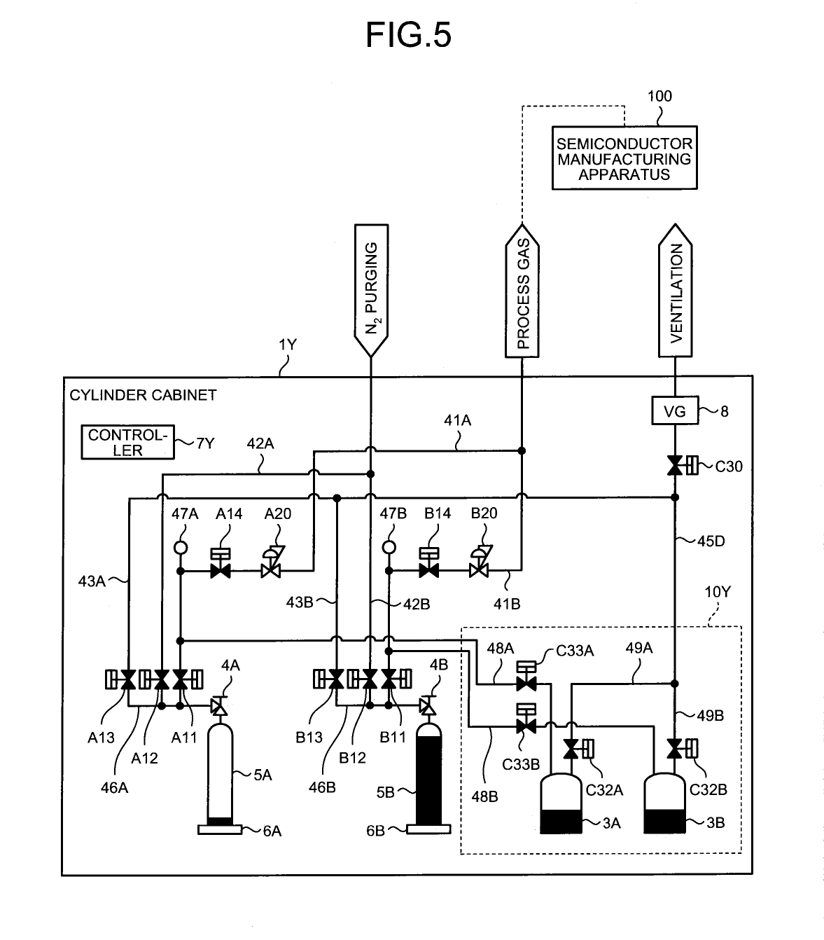

Next, the second embodiment of the present invention will be described with reference to FIGS. 5 to 8. In the second embodiment, the residual gas is recovered using two gas recovery containers, and the recovered residual gas is supplied to the semiconductor manufacturing apparatus as a process gas.

FIG. 5 is a diagram illustrating the configuration of the cylinder cabinet according to the second embodiment. Among the constituent elements shown in FIG. 5, constituent elements having the same functions as those of the cylinder cabinet 1X of the first embodiment shown in FIG. 1 will be denoted by the same reference numerals, and redundant description thereof will not be provided.

A cylinder cabinet 1Y of the present embodiment includes a gas recovery mechanism 10Y instead of the gas recovery mechanism 10X. The gas recovery mechanism 10Y includes gas recovery containers 3A and 3B. The gas recovery container 3A is a container for recovering the residual gas in the gas container 5A, and the gas recovery container 3B is a container for recovering the residual gas in the gas container 5B. Moreover, the gas recovery mechanism 10Y includes automatic valves C32A, C32B, C33A, and C33B, and the cylinder cabinet 1Y includes a controller 7Y instead of the controller 7X.

Moreover, the cylinder cabinet 1Y includes vacuum pipes 45D, 49A, and 49B for vacuuming the gas recovery containers 3A and 3B instead of the vacuum pipe 45C. Moreover, the cylinder cabinet 1Y includes a gas pipe 48A instead of the gas recovery pipe 44A and a gas pipe 48B instead of the gas recovery pipe 44B.

The gas recovery container 3A is connected to the vacuum pipe 49A and the gas pipe 48A, and the gas recovery container 3B is connected to the vacuum pipe 49B and the gas pipe 48B. The vacuum pipes 49A and 49B are connected to the vacuum pipe 45D, and the automatic valve C30 and the VG 8 are provided on the vacuum pipe 45D. Moreover, the vacuum pipe 49A includes the automatic valve C32A, and the vacuum pipe 49B includes the automatic valve C32B.

The gas pipe 48A is a pipe that is connected to the process gas supply pipe 41A on a side closer to the upstream side (the gas container 5A side) more than the automatic valve A14 and is connected to the gas recovery container 3A, and an automatic valve C33A is provided on this pipe. Similarly, the gas pipe 48B is a pipe that is connected to the process gas supply pipe 41B on a side closer to the upstream side (the gas container 5B side) more than the automatic valve B14 and is connected to the gas recovery container 3B, and an automatic valve C33B is provided on this pipe. For example, the gas pipes 48A and 48B are configured to be short. In this way, the residual gases in the gas containers 5A and 5B can be guided to the gas recovery containers 3A and 3B efficiently.

When the process gas is supplied to the semiconductor manufacturing apparatus using the gas container 5A, the valves (the automatic valve B14 and the like) on the side of the gas container 5B are closed. Moreover, the automatic valves A12, A13, and C33A are closed, and the automatic valves A11 and A14 and the container valve 4A are opened.

The controller 7Y controls the supply of the process gas, the recovery of the residual gas, the N₂ purging, the ventilation of the N₂ gas, the process gas purging, and the like by controlling the automatic valves A11 to A14, B11 to B14, C30, C32A, C32B, C33A, and C33B, the pressure adjustment valves A20 and B20, the VG 8, and the like.

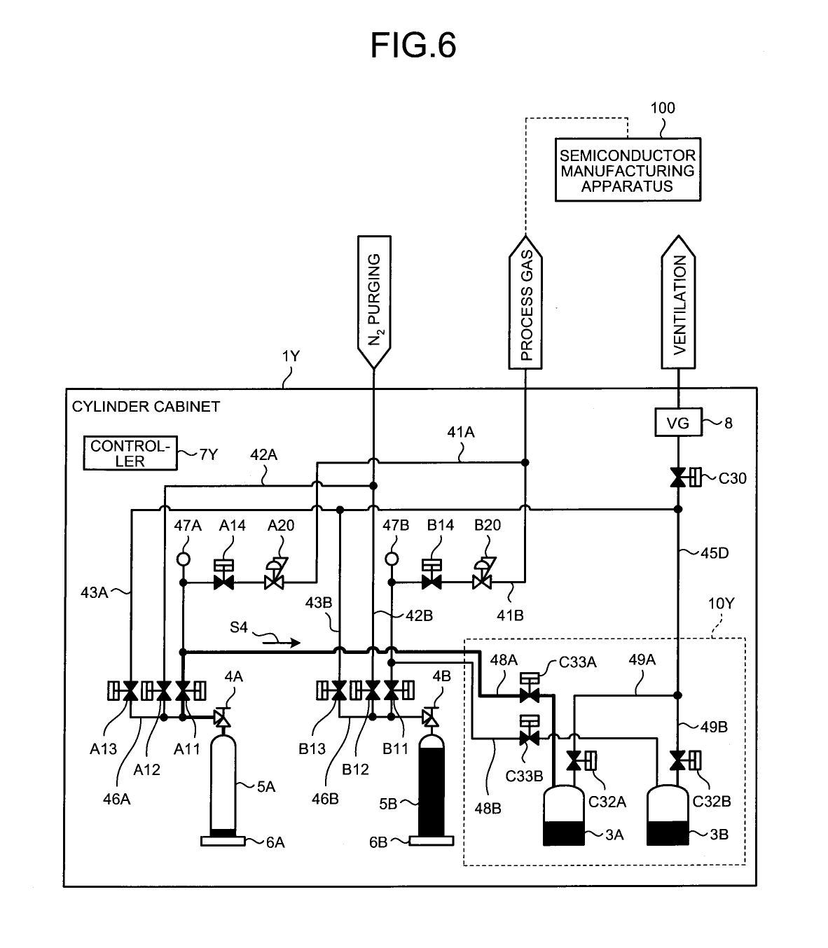

Here, a residual gas recovery process according to the second embodiment will be described. FIG. 6 is a diagram illustrating the internal state of the cylinder cabinet according to the second embodiment when the residual gas is recovered. Here, since the residual gas recovery process using the gas recovery container 3A is the same as the residual gas recovery process using the gas recovery container 3B, the residual gas recovery process using the gas recovery container 3A will be described herein.

When the residual gas in the gas container 5A is recovered into the gas recovery container 3A, the automatic valves C33A, C33B, and C32B are closed, and the automatic valves C30 and C32A are opened. In this way, the inside of the gas recovery container 3A is vacuumed through the vacuum pipes 45D and 49A.

Moreover, after the inside of the gas recovery container 3A is vacuumed, the automatic valve C32A is closed. Furthermore, the automatic valves A12 to A14 are closed, and the automatic valves A11 and C32A and the container valve 4A are opened. In this way, the residual gas is recovered (S4) into the gas recovery container 3A. In other words, the residual gas in the gas container 5A is pulled into the gas recovery container 3A through the container proximity pipe 46A and the gas pipe 48A. After that, when the recovery of the residual gas is completed, the automatic valves A11 and C33A and the container valve 4A are closed.

In the present embodiment, the residual gas is recovered from a plurality of gas containers 5A and stored in the gas recovery container 3A, and the residual gas is recovered from a plurality of gas containers 5B and stored in the gas recovery container 3B. Specifically, after the supply of the process gas using the gas container 5A is finished, the supply of the process gas using the gas container 5B starts, and the residual gas in the gas container 5A (the first one) is stored in the gas recovery container 3A. After that, the gas container 5A is replaced with a new gas container 5A (the second one). Moreover, after the supply of the process gas using the gas container 5B is finished, the supply of the process gas using the gas container 5A starts, and the residual gas in the gas container 5B (the first one) is stored in the gas recovery container 3B. After that, the gas container 5B is replaced with a new gas container 5B.

Furthermore, after the supply of the process gas using the gas container 5A is finished, the supply of the process gas using the gas container 5B starts, and the residual gas in the gas container 5A (the second one) is stored in the gas recovery container 3A. After that, the gas container 5A is replaced with a new gas container 5A (the third one). Moreover, after the supply of the process gas using the gas container 5B is finished, the supply of the process gas using the gas container 5A starts, and the residual gas in the gas container 5B (the second one) is stored in the gas recovery container 3B. After that, the gas container 5B is replaced with a new gas container 5B (the third one).

In the present embodiment, the residual gas recovery process and the replacement process of the gas containers 5A and 5B are repeated a plurality of times. For example, when the residual gas is stored from the second and subsequent gas containers 5A in the gas recovery container 3A, the automatic valve C33A is opened without opening the automatic valve C32A.

The gas recovery container 3A is vacuumed when recovering the residual gas from the first gas container 5A. Thus, it is possible to pull the residual gas in the gas container 5A into the gas recovery container 3A until the pressure of the gas recovery container 3A becomes higher than the pressure of the gas container 5A. In this way, the residual gas corresponding to a predetermined number of gas containers is stored in the gas recovery container 3A. Similarly, the residual gas corresponding to a predetermined number of gas containers is stored in the gas recovery container 3B.

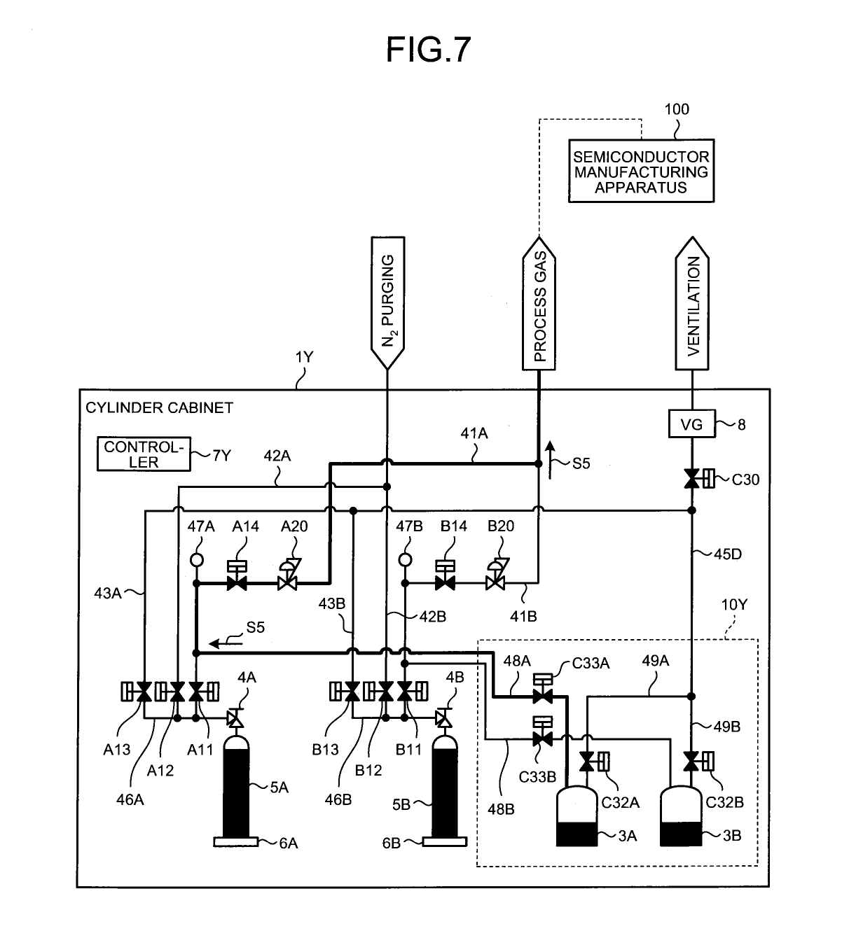

The residual gas in the gas recovery container 3A is supplied to the semiconductor manufacturing apparatus as the process gas, for example. FIG. 7 is a diagram illustrating the internal state of the cylinder cabinet according to the second embodiment when a process gas purging is performed using a recovery gas in a gas recovery container.

When the residual gas in the gas recovery container 3A is supplied to the semiconductor manufacturing apparatus as the process gas, the automatic valves A11 to A13 and C32A are closed, and the automatic valves C33A and A14 are opened. In this way, the residual gas in the gas recovery container 3A is supplied to the semiconductor manufacturing apparatus through the gas pipe 48A and the process gas supply pipe 41A. As above, in the present embodiment, the process gas is supplied using the residual gas (S5) from the gas recovery containers 3A and 3B.

The supply of the process gas from the gas recovery container 3A may be performed at any timing. For example, the process gas is supplied from the gas recovery container 3A after the supply of the process gas from any of the gas containers 5A and 5B and the gas recovery container 3B is finished. Moreover, after the supply of the process gas from the gas recovery container 3A is finished, the supply of the process gas from any of the gas containers 5A and 5B and the gas recovery container 3B starts. More preferably, the process gas is supplied from one recovery container when the residual gas is being recovered from the other recovery container, and the processes are performed. By doing so, it is possible to use the process gas in the gas recovery container without wasting time.

When the gas container 5A is replaced with a new gas container 5A, the process gas purging on the gas container 5A is performed using the gas in the gas container 5A after replacement, for example. Similarly, when the gas container 5B is replaced with a new gas container 5B, the process gas purging on the gas container 5B is performed using the gas in the gas container 5B after replacement, for example.

In the present embodiment, although a case in which the residual gases in the gas recovery containers 3A and 3B are used for supplying the process gas has been described, the residual gases in the gas recovery containers 3A and 3B may be used for purging the process gas.

Moreover, in the present embodiment, although a case in which the residual gas is stored from a plurality of gas containers 5A or 5B into the gas recovery container 3A or 3B has been described, the residual gas may be stored from one gas container 5A or 5B into the gas recovery container 3A or 3B. In this case, the residual gases in the gas recovery containers 3A and 3B are used for purging the process gas.

Moreover, both the gas containers 5A and 5B may be connected to the gas recovery container 3A. Similarly, both the gas containers 5A and 5B may be connected to the gas recovery container 3B. In this case, the gas recovery containers 3A and 3B can recover the residual gas from both the gas containers 5A and 5B.

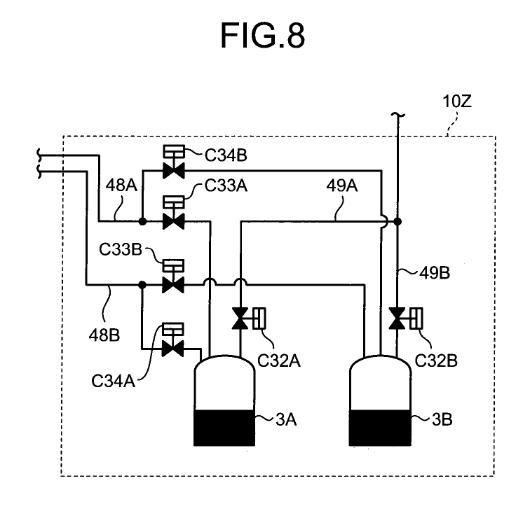

FIG. 8 is a diagram illustrating another configuration example of the gas recovery mechanism. In a gas recovery mechanism 10Z, both gas containers 5A and 5B are connected to the gas recovery container 3A, and both gas containers 5A and 5B are connected to the gas recovery container 3B.

Specifically, the gas pipe 48A is connected to the gas recovery containers 3A and 3B. Moreover, the automatic valve C33A is provided between the gas pipe 48A and the gas recovery container 3A, and an automatic valve C34B is provided between the gas pipe 48A and the gas recovery container 3B. Similarly, the gas pipe 48B is connected to the gas recovery containers 3A and 3B. Moreover, an automatic valve C34A is provided between the gas pipe 48B and the gas recovery container 3A, and the automatic valve C33B is provided between the gas pipe 48B and the gas recovery container 3B.

When the residual gas in the gas container 5A is recovered into the gas recovery container 3A, the automatic valve C33A is opened, and the automatic valve C34B is closed. Moreover, when the residual gas in the gas container 5A is recovered into the gas recovery container 3B, the automatic valve C33A is closed, and the automatic valve C34B is opened. Similarly, when the residual gas in the gas container 5B is recovered into the gas recovery container 3B, the automatic valve C33B is opened, and the automatic valve C34A is closed. Moreover, when the residual gas in the gas container 5B is recovered into the gas recovery container 3A, the automatic valve C33B is closed, and the automatic valve C34A is opened.

For example, when the process gas is supplied from the gas container 5A, the residual gas in the gas container 5B is recovered into the gas recovery container 3A or 3B during the supply. Moreover, when the process gas is supplied from the gas container 5B, the residual gas in the gas container 5A is recovered into the gas recovery container 3A or 3B during the supply.

Moreover, when the residual gas is supplied from the gas recovery container 3A as the process gas, the residual gas in the gas container 5A or 5B is recovered into the gas recovery container 3B during the supply. Moreover, when the residual gas is supplied from the gas recovery container 3B as the process gas, the residual gas in the gas container 5A or 5B is recovered into the gas recovery container 3A during the supply.

As above, according to the second embodiment, the residual gas is stored from a plurality of gas containers 5A and 5B into the gas recovery containers 3A and 3B and supplied as the process gas, it is possible to reduce wasteful discarding of gas.

As described above, according to the first and second embodiments, it is possible to reduce wasteful discarding of gas.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A cylinder cabinet comprising:
a first gas supply pipe that is connected to a first gas container for gas to be supplied to an external apparatus so as to supply the gas in the first gas container toward the external apparatus;
a second gas supply pipe that is connected to a second gas container for gas to be supplied to the external apparatus so as to supply the gas in the second gas container toward the external apparatus;
a gas recovery pipe that is connected to a recovery container for recovering and storing the residual gases in the first and second gas containers so as to supply the residual gas in the first and second gas containers toward the recovery container;
a vacuum pipe that is connected to the recovery container so as to vacuum the inside of the recovery container before the residual gas is stored in the recovery container;
automatic valves that are provided on the first and second gas supply pipes, the gas recovery pipe, and the vacuum pipe, respectively so as to close or open the flow of the gas; and
a controller that controls the automatic valves to thereby control the flow of the gas and the residual gas so that the gas is supplied to the external apparatus through any one of the first and second gas supply pipes,
wherein the controller performs control in such a way that
when the amount of the residual gas in the first gas container becomes a predetermined amount or smaller, a gas supply pipe that supplies the gas is switched from the first gas supply pipe to the second gas supply pipe,
the residual gas in the first gas container is recovered into the recovery container during a period in which the gas is supplied from the second gas container, and
when the first gas container is replaced with a new gas container, the inside of the first gas supply pipe is purged with the residual gas stored in the recovery container.

2. The cylinder cabinet according to claim 1,
wherein during the purging, the gas in the recovery container is supplied into the first gas supply pipe through the gas recovery pipe.

3. The cylinder cabinet according to claim 1,
wherein the controller performs control in such a way that
when the amount of the residual gas in the second gas container becomes a predetermined amount or smaller, the gas supply pipe that supplies the gas is switched from the second gas supply pipe to the first gas supply pipe,
the residual gas in the second gas container is recovered into the recovery container during a period in which the gas is supplied from the first gas container, and
when the second gas container is replaced with a new gas container, the inside of the second gas supply pipe is purged with the residual gas stored in the recovery container.

4. The cylinder cabinet according to claim 1,
wherein during the purging, the gas in the recovery container is supplied into the second gas supply pipe through the gas recovery pipe.

5. A cylinder cabinet comprising:
a first gas supply pipe that is connected to a first gas container for gas to be supplied to an external apparatus so as to supply the gas in the first gas container toward the external apparatus;
a second gas supply pipe that is connected to a second gas container for gas to be supplied to the external apparatus so as to supply the gas in the second gas container toward the external apparatus;
a first gas recovery pipe that is connected to a first recovery container for recovering and storing the residual gases in the first gas container so as to supply the residual gas in the first gas container toward the first recovery container;
a second gas recovery pipe that is connected to a second recovery container for recovering and storing the residual gases in the second gas container so as to supply the residual gas in the second gas container toward the second recovery container;
a vacuum pipe that is connected to the first and second recovery containers so as to vacuum the inside of the first or second recovery container before the residual gas is stored in the first or second recovery container;
automatic valves that are provided on the first and second gas supply pipes, the first and second gas recovery pipes, and the vacuum pipe, respectively so as to close or open the flow of the gas; and
a controller that controls the automatic valves to thereby control the flow of the gas and the residual gas so that the gas is supplied to the external apparatus through any one of the first and second gas containers and the first and second recovery containers,
wherein the controller performs control in such a way that
the residual gas in the first gas container is recovered into the first or second recovery container during a period in which the gas is supplied from the second gas container, and the residual gas in the second gas container is recovered into the first or second recovery container during a period in which the gas is supplied from the first gas container, and
when the residual gas is stored into the first or second recovery container, the residual gas corresponding to a plurality of the first or second gas containers is stored in the first and second recovery containers.

6. The cylinder cabinet according to claim 5,
wherein the controller performs control in such a way that the residual gas in the first or second gas container is recovered into the first recovery container during a period in which the gas is supplied from the second recovery container.

7. The cylinder cabinet according to claim 5,
wherein the controller performs control in such a way that the residual gas in the first or second gas container is recovered into the second recovery container during a period in which the gas is supplied from the first recovery container.

8. The cylinder cabinet according to claim 5,
wherein when the gas is supplied to the external apparatus, the gas in the first or second recovery container is supplied into the first or second gas supply pipe through the first or second gas recovery pipe.

9. The cylinder cabinet according to claim 5,
wherein the inside of the first gas supply pipe is purged with the residual gas stored in the first or second recovery container when the first gas container is replaced, and the inside of the second gas supply pipe is purged with the residual gas stored in the first or second recovery container when the second gas container is replaced.

10. The cylinder cabinet according to claim 5,
wherein when the inside of the first gas supply pipe is purged with the residual gas stored in the first or second recovery container, the gas in the first or second recovery container is supplied into the first gas supply pipe through the first or second gas recovery pipe.

11. The cylinder cabinet according to claim 5,
wherein when the inside of the second gas supply pipe is purged with the residual gas stored in the first or second recovery container, the gas in the first or second recovery container is supplied into the second gas supply pipe through the first or second gas recovery pipe.

12. The cylinder cabinet according to claim 5,
wherein the controller performs control in such a way that when the amount of the residual gas in the first gas container becomes a predetermined amount or smaller, a pipe that supplies the gas is switched from the first gas supply pipe to the second gas supply pipe and the first or second recovery container.

13. The cylinder cabinet according to claim 5,
wherein the controller performs control in such a way that when the amount of the residual gas in the second gas container becomes a predetermined amount or smaller, a pipe that supplies the gas is switched from the second gas supply pipe to the first gas supply pipe and the first or second recovery container.

14. A semiconductor manufacturing system comprising:
a semiconductor manufacturing apparatus that manufactures semiconductor devices using gas;
a first gas supply pipe that is connected to a first gas container for gas to be supplied to the semiconductor manufacturing apparatus so as to supply the gas in the first gas container toward the semiconductor manufacturing apparatus;
a second gas supply pipe that is connected to a second gas container for gas to be supplied to the semiconductor manufacturing apparatus so as to supply the gas in the second gas container toward the semiconductor manufacturing apparatus;
a first gas recovery pipe that is connected to a first recovery container for recovering and storing the residual gases in the first gas container so as to supply the residual gas in the first gas container toward the first recovery container;
a second gas recovery pipe that is connected to a second recovery container for recovering and storing the residual gases in the second gas container so as to supply the residual gas in the second gas container toward the second recovery container;
a vacuum pipe that is connected to the first and second recovery containers so as to vacuum the inside of the first or second recovery container before the residual gas is stored in the first or second recovery container;
automatic valves that are provided on the first and second gas supply pipes, the first and second gas recovery pipes, and the vacuum pipe, respectively so as to close or open the flow of the gas; and
a controller that controls the automatic valves to thereby control the flow of the gas and the residual gas so that the gas is supplied to the semiconductor manufacturing apparatus through any one of the first and second gas containers and the first and second recovery containers,
wherein the controller performs control in such a way that
the residual gas in the first gas container is recovered into the first or second recovery container during a period in which the gas is supplied from the second gas container, and the residual gas in the second gas container is recovered into the first or second recovery container during a period in which the gas is supplied from the first gas container, and
when the residual gas is stored into the first or second recovery container, the residual gas corresponding to a plurality of the first or second gas containers is stored in the first and second recovery containers.

15. The semiconductor manufacturing system according to claim 14,
wherein the controller performs control in such a way that the residual gas in the first or second gas container is recovered into the first recovery container during a period in which the gas is supplied from the second recovery container.

16. The semiconductor manufacturing system according to claim 14,
wherein the controller performs control in such a way that the residual gas in the first or second gas container is recovered into the second recovery container during a period in which the gas is supplied from the first recovery container.

17. The semiconductor manufacturing system according to claim 14,
wherein when the gas is supplied to the external apparatus, the gas in the first or second recovery container is supplied into the first or second gas supply pipe through the first or second gas recovery pipe.

18. The semiconductor manufacturing system according to claim 14,
wherein the inside of the first gas supply pipe is purged with the residual gas stored in the first or second recovery container when the first gas container is replaced, and the inside of the second gas supply pipe is purged with the residual gas stored in the first or second recovery container when the second gas container is replaced.

19. The semiconductor manufacturing system according to claim 14,
wherein when the inside of the first gas supply pipe is purged with the residual gas stored in the first or second recovery container, the gas in the first or second recovery container is supplied into the first gas supply pipe through the first or second gas recovery pipe.

20. The semiconductor manufacturing system according to claim 14,
wherein when the inside of the second gas supply pipe is purged with the residual gas stored in the first or second recovery container, the gas in the first or second recovery container is supplied into the second gas supply pipe through the first or second gas recovery pipe.
